(19) United States
(12) Patent Application Publication
(10) Pub. No.: US 2025/0187308 A1
(43) Pub. Date: Jun. 12, 2025

(54) LAMINATE

(71) Applicant: FUJIFILM Corporation, Tokyo (JP)

(72) Inventors: Koji HIRONAKA, Kanagawa (JP); Sotaro INOMATA, Kanagawa (JP)

(73) Assignee: FUJIFILM Corporation, Tokyo (JP)

(21) Appl. No.: 19/055,504

(22) Filed: Feb. 18, 2025

Related U.S. Application Data
(63) Continuation of application No. PCT/JP2023/033752, filed on Sep. 15, 2023.

(30) Foreign Application Priority Data
Sep. 30, 2022 (JP) 2022-157310

(51) Int. Cl. B32B 15/09; B32B 15/20

(52) U.S. Cl. CPC B32B 15/09; B32B 15/20; B32B 2305/55

(57) ABSTRACT

An object of the present invention is to provide a laminate having excellent low dielectric characteristics, low water absorption, and adhesiveness. The laminate of the present invention includes a copper layer and a polymer layer, in which the polymer layer contains a polyarylate, and the polyarylate has at least one repeating unit I selected from the group consisting of a repeating unit represented by Formula (I-A), a repeating unit represented by Formula (I-B), and a repeating unit represented by Formula (I-C), and has a repeating unit II represented by Formula (II).

### CROSS-REFERENCE TO RELATED APPLICATIONS

This application is a Continuation of PCT International Application No. PCT/JP2023/033752 filed on Sep. 15, 2023, which claims priority under 35 U.S.C. § 119(a) to Japanese Patent Application No. 2022-157310 filed on Sep. 30, 2022. The above applications are hereby expressly incorporated by reference, in their entirety, into the present application.

### BACKGROUND OF THE INVENTION

### 1. Field of the Invention

The present invention relates to a laminate.

### 2. Description of the Related Art

The speed and capacity of signals in mobile communication devices such as mobile phones, network infrastructure devices such as servers and routers, and electronic apparatuses such as large computers have been increased year by year, and particularly, a rapid growth of fifth generation mobile communication systems (5G) is expected. For example, a high-frequency circuit board (for example, a printed wiring board such as a rigid substrate and a flexible substrate) is mounted on these electronic apparatuses. In addition, in recent years, as an application using such a high-frequency signal, a new system using a high-frequency wireless signal is put into practical use and a practical plan is made in the field of intelligent transport systems (ITS) (for example, automobile and transportation system-related) and the field of short-range communication indoors, and the high-frequency circuit board is also used for these devices and the like.
In such a high-frequency circuit board, a laminate having a polymer layer and a metal layer (for example, metallic copper and metallic aluminum) is often used.

As a polymer constituting the polymer layer, for example, JP2018-066018A discloses “polyarylate resin containing a divalent phenol residue represented by General Formula (1) and an aromatic divalent carboxylic acid residue represented by General Formula (2) and General Formula (3)”.

### SUMMARY OF THE INVENTION

A laminate used for a high-frequency circuit board or the like is required to have excellent low dielectric characteristics and excellent low water absorption. In addition, it is also required that adhesiveness between the polymer layer and the copper layer is excellent.

As a result of studying the invention disclosed in JP2018-066018A, the present inventors have found that it is difficult to achieve a balance between low dielectric characteristics, low water absorption, and adhesiveness.

Therefore, an object of the present invention is to provide a laminate having excellent low dielectric characteristics, low water absorption, and adhesiveness.

As a result of intensive studies on the above-described objects, the present inventors have found that the above-described objects can be accomplished by the following configurations.
[1]

A laminate comprising:
a copper layer; and
a polymer layer,
in which the polymer layer contains a polyarylate, and
the polyarylate has at least one repeating unit I selected from the group consisting of a repeating unit represented by Formula (I-A) described later, a repeating unit represented by Formula (I-B) described later, and a repeating unit represented by Formula (I-C) described later, and has a repeating unit II represented by Formula (II) described later.
[2]

The laminate according to [1],
in which the polymer layer further contains a liquid crystal polymer different from the polyarylate.
[3]

The laminate according to [1] or [2],
in which the polyarylate has a crosslinking structure.
[4]

The laminate according to any one of [1] to [3],
in which the polyarylate has only a repeating unit represented by Formula (I-Aa) described later as the repeating unit I.

According to the present invention, it is possible to provide a laminate having excellent low dielectric characteristics, low water absorption, and adhesiveness.

### DESCRIPTION OF THE PREFERRED EMBODIMENTS

In the present specification, numerical ranges represented by “to” include numerical values before and after “to” as lower limit values and upper limit values.
In the present specification, in a case where a polymer has a plurality of repeating units having the same representation (represented by the same general formula), the repeating units may be the same or different from each other.

### Laminate

The laminate according to the embodiment of the present invention includes a copper layer and a polymer layer, in which the polymer layer contains a polyarylate, and the polyarylate has at least one repeating unit I selected from the group consisting of a repeating unit represented by Formula (I-A), a repeating unit represented by Formula (I-B), and a repeating unit represented by Formula (I-C), and has a repeating unit II represented by Formula (II).
Hereinafter, the polyarylate having at least one repeating unit I selected from the group consisting of a repeating unit represented by Formula (I-A), a repeating unit represented by Formula (I-B), and a repeating unit represented by Formula (I-C), and having the repeating unit II represented by Formula (II) is referred to as “specific polyarylate”.

The laminate according to the embodiment of the present invention includes a polymer layer containing the specific polyarylate.
As described above, a high-frequency circuit board needs to simultaneously satisfy the required levels of various characteristics such as low dielectric characteristics. It has been confirmed that, in the polyarylate of the related art (for example, Comparative Example 1 and the like), both the low dielectric characteristics and the low water absorption do not satisfy the required levels, and the adhesiveness to the copper layer from which the circuit wiring is derived is also deteriorated. On the other hand, it is confirmed that, in a case of using a polymer layer containing a polyarylate which has a specific repeating unit such as the specific polyarylate, the low dielectric characteristics, the low water absorption, and the adhesiveness between the polymer layer and the copper layer are all excellent, and a remarkable effect which is difficult to be expected is exhibited.
Hereinafter, the fact that at least one effect of being more excellent in low dielectric characteristics, being more excellent in low water absorption, or being more excellent in adhesiveness between the polymer layer and the copper layer is obtained is also referred to as “effect of the present invention is more excellent”.

Hereinafter, each member which can be included in the laminate will be described in detail.

### Copper Layer

The laminate includes a copper layer.
The copper layer is not particularly limited as long as it is a layer containing metallic copper.
The copper layer (preferably, an interface with the polymer layer) may be subjected to a surface reforming treatment.
Examples of the surface reforming treatment include discharge treatments such as a corona discharge treatment, a glow discharge treatment, a plasma discharge treatment, and a sputtering treatment; an ultraviolet treatment, an electron beam treatment, and a silane coupling treatment.

Examples of the copper layer include a rolled copper foil and an electrolytic copper foil.
Examples of the rolled copper foil include TPC foil (manufactured by JX Advanced Metals Corporation), HA foil (manufactured by JX Advanced Metals Corporation), HA-V2 foil (manufactured by JX Advanced Metals Corporation), and C1100R (manufactured by Sumitomo Metal Mining Co., Ltd.).
Examples of the electrolytic copper foil include CF-T4X-SV-18 (manufactured by FUKUDA METAL FOIL & POWDER CO., LTD.), F0-WS-18 (manufactured by FURUKAWA ELECTRIC CO., LTD.), NC-WS-20 (manufactured by FURUKAWA ELECTRIC CO., LTD.), YGP-12 (manufactured by NIPPON ELECTROLYTIC COPPER CO., LTD.), GTS-18 (manufactured by FURUKAWA ELECTRIC CO., LTD.), and F2-WS-12 (manufactured by FURUKAWA ELECTRIC CO., LTD.).

The copper layer may have a wiring pattern.
Examples of a method of forming the wiring pattern on the copper layer include a known etching treatment.

A surface roughness Rz of the copper layer (preferably, the interface with the polymer layer) is preferably 2.0 μm or less, and more preferably 1.0 μm or less. The lower limit thereof is preferably 0.01 μm or more.
The surface roughness Rz can be measured by a known method.
A thickness of the copper layer is preferably 5 to 50 μm and more preferably 9 to 35 μm.

### Polymer Layer

The laminate includes a polymer layer containing the specific polyarylate.
The laminate may include one or a plurality (preferably two or three) of polymer layers. In other words, the polymer layer may be a single layer or a multilayer. In addition, in a case where the polymer layer is a multilayer, the respective polymer layers may be in direct contact with each other, or another layer may be provided between the polymer layer and the polymer layer.
In a case where the laminate includes a plurality of polymer layers, it is sufficient that at least one polymer layer among the plurality of polymer layers contains the specific polyarylate, and the laminate may further include a polymer layer which does not contain the specific polyarylate.

### Specific Polyarylate

The specific polyarylate has at least one repeating unit I selected from the group consisting of a repeating unit represented by Formula (I-A), a repeating unit represented by Formula (I-B), and a repeating unit represented by Formula (I-C), and has a repeating unit II represented by Formula (II).
As the repeating unit I, at least one selected from the group consisting of a repeating unit represented by Formula (I-A) and a repeating unit represented by Formula (I-B) is preferable; a repeating unit represented by Formula (I-A) is more preferable; and a repeating unit represented by Formula (I-Aa) is still more preferable.
In addition, the specific polyarylate preferably has only a repeating unit represented by Formula (I-A) as the repeating unit I, and more preferably has only a repeating unit represented by Formula (I-Aa) as the repeating unit I.

### Repeating Unit Represented by Formula (I-A)

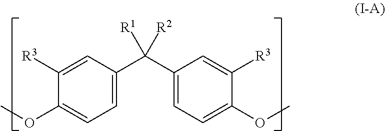

In Formula (I-A), R¹ represents a branched alkyl group having 4 or more carbon atoms.
R² represents a hydrogen atom, a linear alkyl group, or an aryl group which may have a substituent.
R³ represents a hydrogen atom, an alkyl group, or an aryl group which may have a substituent.
However, R¹ and R² are not bonded to each other to form a ring structure.

In Formula (I-A), R¹ represents a branched alkyl group having 4 or more carbon atoms.
The number of carbon atoms in R¹ is preferably 4 to 20, more preferably 4 to 15, still more preferably 4 to 10, and particularly preferably 4 to 8.
Examples of R¹ include 1-methylpropyl group, 2-methylpropyl group, 1,2-dimethylpropyl group, 2,2-dimethylpropyl group, 1-ethylpropyl group, 1-methylbutyl group, 2-methylbutyl group, 3-methylbutyl group, 1-ethylbutyl group, 2-ethylbutyl group, 1,1-dimethylbutyl group, 1,2-dimethylbutyl group, 1,3-dimethylbutyl group, 2,2-dimethylbutyl group, 3,3-dimethylbutyl group, 4-methylpentyl group, 1-ethylpentyl group, 2-ethylpentyl group, 3-ethylpentyl group, 1,3-dimethylpentyl group, 1,4-dimethylpentyl group, 2,4,4-trimethylpentyl group, 1-ethylheptyl group, 2-ethylheptyl group, 3-methylhexyl group, and 11-methyldodecyl group.
Among these, as R¹, 1-methylpropyl group, 2-methylpropyl group, 1-methylbutyl group, 3-methylbutyl group, 1-ethylpropyl group, 1-ethylbutyl group, 1-ethylpentyl group, 1-ethylhexyl group, 1-ethylheptyl group, or 2,4,4-trimethylpentyl group is preferable; and 2-methylpropyl group, 1-ethylbutyl group, 1-ethylpentyl group, 2,4,4-trimethylpentyl group, or 1-ethylheptyl group is more preferable.

In Formula (I-A), R² represents a hydrogen atom, a linear alkyl group, or an aryl group which may have a substituent.
The number of carbon atoms in the linear alkyl group represented by R² is preferably 1 to 10, more preferably 1 to 6, and still more preferably 1 to 4.
As the linear alkyl group represented by R², a methyl group or an ethyl group is preferable, and a methyl group is more preferable.
The number of carbon atoms in the aryl group which may have a substituent, represented by R², is preferably 6 to 26, more preferably 6 to 20, still more preferably 6 to 15, particularly preferably 6 to 12, and most preferably 6 to 10.
As the aryl group which may have a substituent, represented by R², a phenyl group, a 4-methoxyphenyl group, a 4-acetoxyphenyl group, a 1-naphthyl group, or a 2-naphthyl group is preferable.
R² is preferably a hydrogen atom or a methyl group.

In Formula (I-A), R³ represents a hydrogen atom, an alkyl group, or an aryl group which may have a substituent.
The alkyl group represented by R³ may be linear, branched, or cyclic.
The number of carbon atoms in the alkyl group represented by R³ is preferably 1 to 10, more preferably 1 to 6, and still more preferably 1 to 4.
As the alkyl group represented by R³, a methyl group or an ethyl group is preferable, and a methyl group is more preferable.
The aryl group which may have a substituent, represented by R³, is the same as the aryl group which may have a substituent, represented by R²; and a suitable aspect thereof is also the same.
R³ is preferably a hydrogen atom or a methyl group.

In Formula (I-A), R¹ and R² are not bonded to each other to form a ring structure.
In a case where R¹ and R² are not bonded to each other to form a ring structure, various characteristics such as the low dielectric characteristics are excellent.

As the repeating unit represented by Formula (I-A), a repeating unit represented by Formula (I-Aa) is preferable.

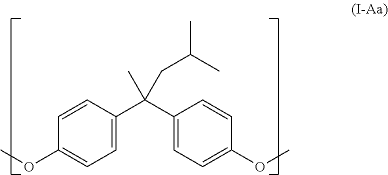

### Repeating Unit Represented by Formula (I-B)

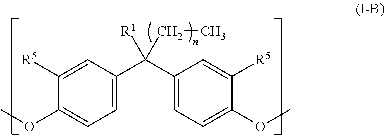

In Formula (I-B), R⁴ represents a hydrogen atom, a linear alkyl group, or an aryl group which may have a substituent.
R⁵ represents a hydrogen atom, an alkyl group, or an aryl group which may have a substituent.
n represents an integer of 2 to 20.

In Formula (I-B), R⁴ represents a hydrogen atom, a linear alkyl group, or an aryl group which may have a substituent.
The linear alkyl group represented by R⁴ is the same as the linear alkyl group represented by R², and a suitable aspect thereof is also the same.
The aryl group which may have a substituent, represented by R⁴, is the same as the aryl group which may have a substituent, represented by R²; and a suitable aspect thereof is also the same.
R⁴ is preferably a hydrogen atom or a methyl group.

In Formula (I-B), n represents an integer of 2 to 20.
In a case where n is an integer of 2 to 20, solubility of the specific polyarylate in a solvent and compatibility with a functional material are easily improved, and the formation of the polymer layer and the expression of the function are easily performed.
n is preferably an integer of 3 to 20, more preferably an integer of 4 to 20, still more preferably an integer of 4 to 15, particularly preferably an integer of 5 to 13, and most preferably an integer of 6 to 10.

### Repeating Unit Represented by Formula (I-C)

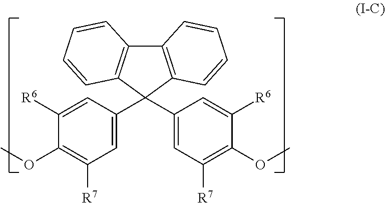

In Formula (I-C), R⁶ and R⁷ represent a hydrogen atom, an alkyl group, or an aryl group which may have a substituent.
In Formula (I-C), R⁶ and R⁷ are the same as R³, and suitable aspects thereof are also the same.

Specific examples of the repeating unit represented by Formula (I-A) are shown below. In the formulae, Me represents a methyl group.

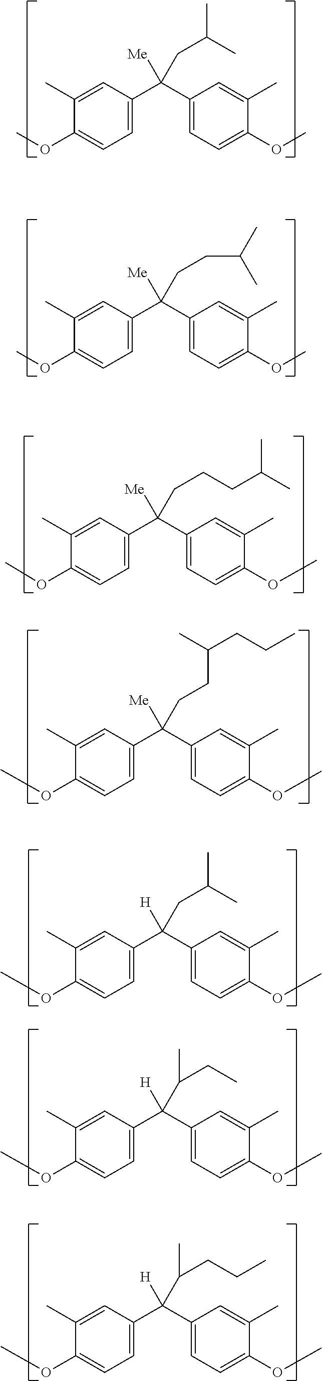

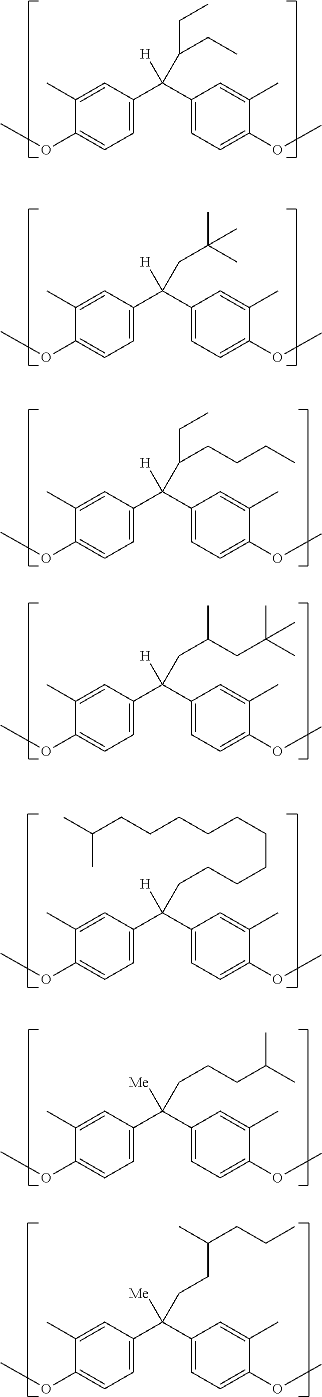

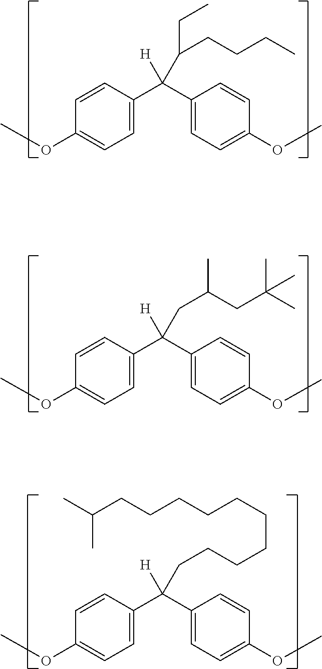

Specific examples of the repeating unit represented by Formula (I-B) are shown below. In the formulae, Me represents a methyl group.

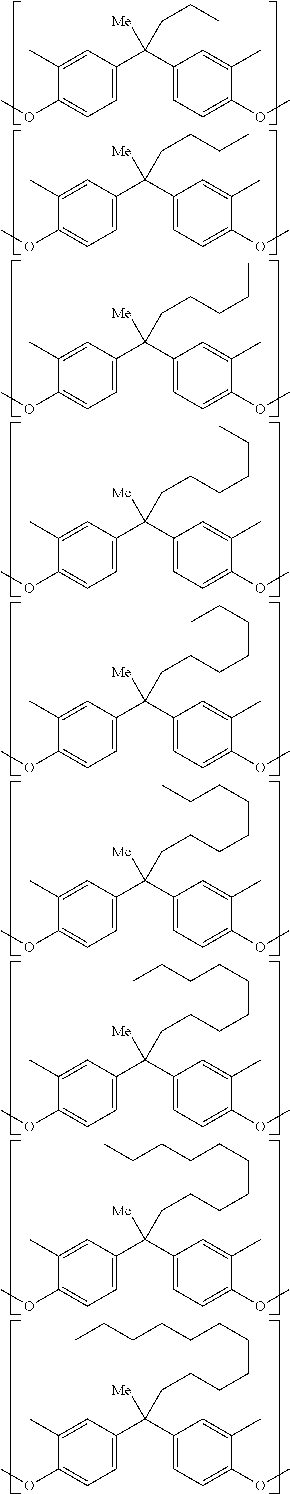

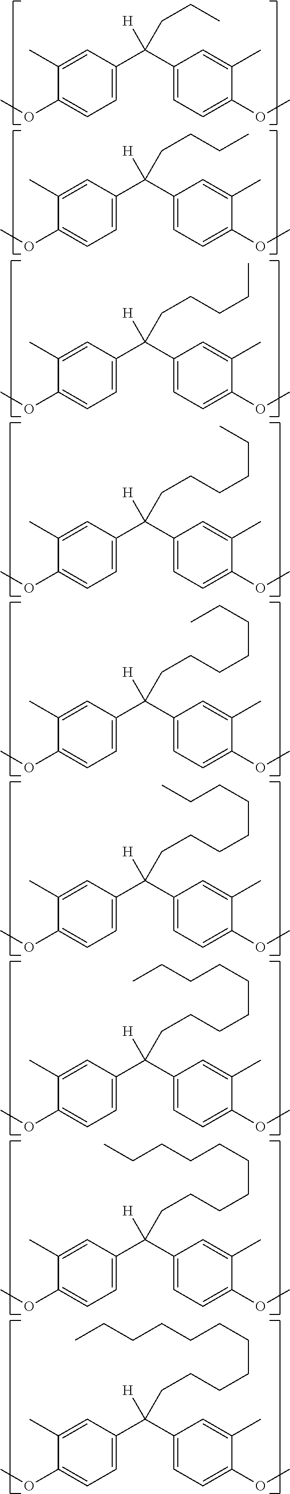

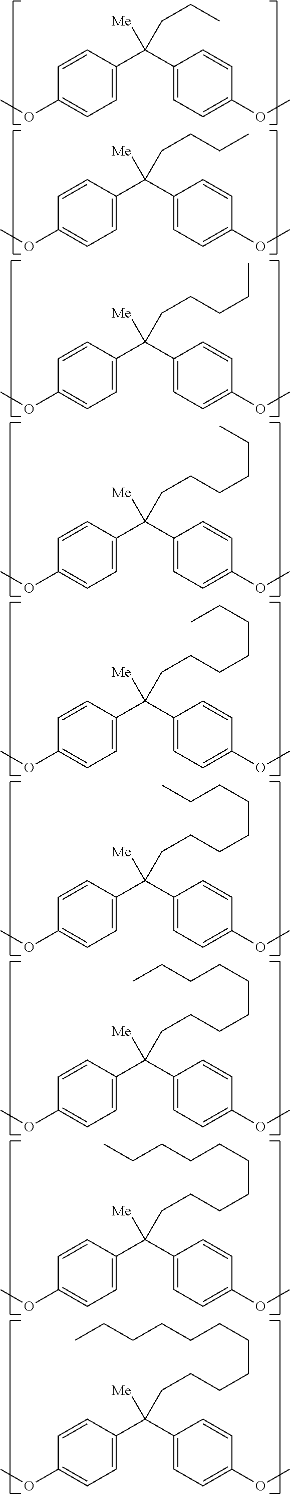

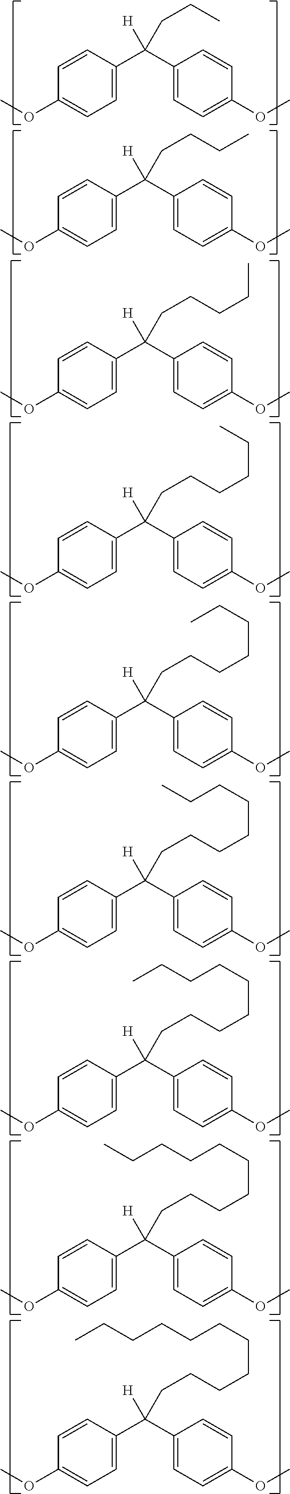

Specific examples of the repeating unit represented by Formula (I-C) are shown below.

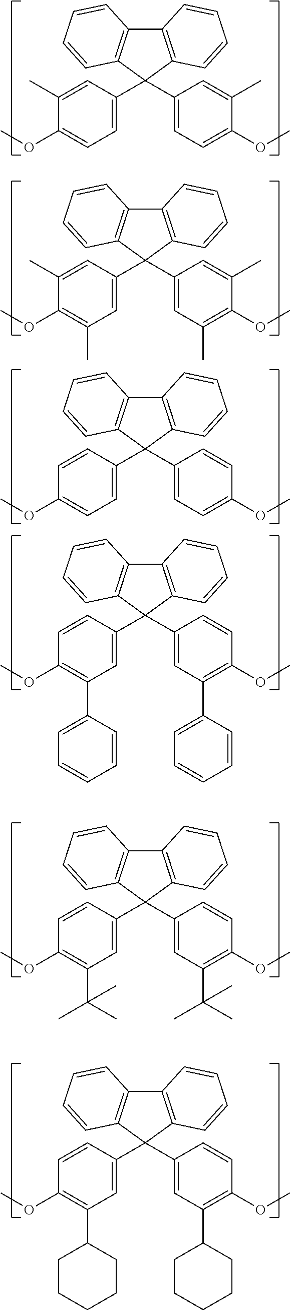

A content of the repeating unit I in the specific polyarylate is preferably 10% by mass or more, more preferably 20% by mass or more, still more preferably 30% by mass or more, and particularly preferably 40% by mass or more with respect to the total mass of the specific polyarylate. The upper limit thereof is preferably 70% by mass or less, and more preferably 60% by mass or less with respect to the total mass of the specific polyarylate.
A content of the repeating unit represented by Formula (I-A) in the specific polyarylate is preferably 10% by mass or more, more preferably 20% by mass or more, still more preferably 30% by mass or more, and particularly preferably 40% by mass or more with respect to the total mass of the specific polyarylate. The upper limit thereof is preferably 70% by mass or less, and more preferably 60% by mass or less with respect to the total mass of the specific polyarylate.
A content of the repeating unit represented by Formula (I-B) in the specific polyarylate is preferably 10% by mass or more, more preferably 20% by mass or more, still more preferably 30% by mass or more, and particularly preferably 40% by mass or more with respect to the total mass of the specific polyarylate. The upper limit thereof is preferably 70% by mass or less, and more preferably 60% by mass or less with respect to the total mass of the specific polyarylate.
A content of the repeating unit represented by Formula (I-C) in the specific polyarylate is preferably 10% by mass or more, and more preferably 20% by mass or more with respect to the total mass of the specific polyarylate. The upper limit thereof is preferably 70% by mass or less, more preferably 60% by mass or less, still more preferably 50% by mass or less, and particularly preferably 40% by mass or less with respect to the total mass of the specific polyarylate.

### Repeating Unit II

The specific polyarylate has a repeating unit II represented by Formula (II).

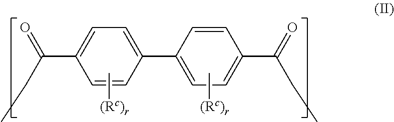

In Formula (II), R^{c} represents an alkyl group, an aryl group which may have a substituent, or a halogen atom.
r represents an integer of 0 to 4.

The alkyl group represented by R^{c} and the aryl group which may have a substituent, represented by R^{c}, are each the same as the alkyl group represented by R³ and the aryl group which may have a substituent, represented by R³; and suitable aspects thereof are also the same.
Examples of the halogen atom represented by R^{c} include a fluorine atom, a chlorine atom, a bromine atom, and an iodine atom.
R^{c} is preferably a hydrogen atom or a methyl group.
r is preferably 0 or 2, and more preferably 0.

A content of the repeating unit II in the specific polyarylate is preferably 10% by mass or more, more preferably 20% by mass or more, still more preferably 30% by mass or more, and particularly preferably 40% by mass or more with respect to the total mass of the specific polyarylate. The upper limit thereof is preferably 70% by mass or less, and more preferably 60% by mass or less with respect to the total mass of the specific polyarylate.

The specific polyarylate may have other repeating units in addition to the above-described repeating units.
Examples of the other repeating units include a repeating unit derived from a dicarboxylic acid.
Examples of the above-described dicarboxylic acid include 4,4′-diphenyl ether dicarboxylic acid, 1,4-cyclohexanedicarboxylic acid, terephthalic acid, isophthalic acid, orthophthalic acid, 1,4-naphthalenedicarboxylic acid, 2,3-naphthalenedicarboxylic acid, 2,6-naphthalenedicarboxylic acid, adipic acid, pimelic acid, suberic acid, azelaic acid, sebacic acid, undecanedioic acid, dodecanedioic acid, tridecanedioic acid, tetradecanedioic acid, pentadecanedioic acid, octadecanedioic acid, nonadecanedioic acid, and eicosanedioic acid.
As the above-described dicarboxylic acid, 4,4′-diphenylether dicarboxylic acid, 2,6-naphthalenedicarboxylic acid, or terephthalic acid is preferable.

A content of the other repeating units in the specific polyarylate is preferably 10% to 60% by mass, more preferably 20% to 50% by mass, and still more preferably 30% to 50% by mass with respect to the total mass of the specific polyarylate.

The specific polyarylate preferably has a crosslinking structure.
The crosslinking structure is not particularly limited, but in a case where the polymer layer is formed of a composition for forming a polymer layer containing a crosslinking agent, which will be described later, a crosslinking structure formed by linking the specific polyarylates to each other as a part of the structure is preferable.

A weight-average molecular weight of the specific polyarylate is preferably 50,000 to 250,000, more preferably 80,000 to 180,000, and still more preferably 100,000 to 150,000.
In the present specification, a molecular weight of a polymer such as the specific polyarylate is a weight-average molecular weight unless otherwise specified. The weight-average molecular weight is a polystyrene-equivalent value determined by gel permeation chromatography (GPC). As an eluent in GPC, tetrahydrofuran is preferable. A suitable aspect of the above-described weight-average molecular weight is a polystyrene-equivalent value measured using tetrahydrofuran as an eluent.

The specific polyarylate may be used alone or in combination of two or more kinds thereof.
A content of the specific polyarylate is usually 1% to 100% by mass, preferably 5% to 65% by mass, more preferably 15% to 55% by mass, and still more preferably 20% to 45% by mass with respect to the total mass of the polymer layer.
In the present specification, in a case where the laminate includes a single polymer layer, the content of the specific polyarylate is a value with respect to the total mass of the single polymer layer. In addition, in a case where the laminate includes a plurality of polymer layers, the content of the specific polyarylate is a value with respect to the total mass of each single polymer layer, and is not a value with respect to the total mass of the plurality of polymer layers.
Contents of various components shown below are the same as described above, unless otherwise specified.

### Liquid Crystal Polymer

The polymer layer may contain a liquid crystal polymer.
The liquid crystal polymer is a polymer which is different from the specific polyarylate and does not correspond to the specific polyarylate (does not satisfy the requirements of the specific polyarylate).

The liquid crystal polymer may be a thermotropic liquid crystal polymer which exhibits liquid crystallinity in a molten state.
Examples of the thermotropic liquid crystal polymer include thermotropic liquid crystal polyester and thermotropic liquid crystal polyester amide.
In addition, at least one structure selected from the group consisting of an imide bond, a urethane bond, a carbodiimide bond, a carbonate bond, and an isocyanurate bond may be introduced into the thermotropic liquid crystal polyester or the thermotropic liquid crystal polyester amide.
The liquid crystal polymer may have a repeating unit derived from p-hydroxybenzoic acid and/or a repeating unit derived from 6-hydroxy-2-naphthoic acid.

The liquid crystal polymer preferably has a repeating unit represented by any of Formulae (LC1) to (LC4).

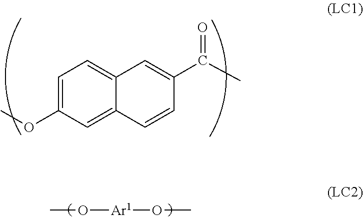

In Formula (LC2), Ar¹ represents a phenyl group, a biphenyl group, a naphthyl group, an anthryl group, or a phenanthryl group, each of which may have a substituent.
As Ar¹, a phenyl group which may have a substituent or a biphenyl group which may have a substituent is preferable.
As the substituent which can be included in the group represented by Ar¹, an alkyl group, an alkoxy group, or a fluorine atom is preferable.

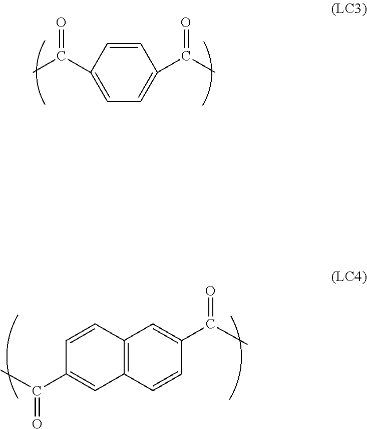

A content of the repeating unit represented by Formula (LC1) is preferably 10 to 80 mol % and more preferably 50 to 65 mol % with respect to the total mass of the liquid crystal polymer.
A content of the repeating unit represented by Formula (LC2) is preferably 1 to 50 mol % and more preferably 15 to 25 mol % with respect to the total mass of the liquid crystal polymer.
A content of the repeating unit represented by Formula (LC3) is preferably 1 to 50 mol % and more preferably 10 to 25 mol % with respect to the total mass of the liquid crystal polymer.
A content of the repeating unit represented by Formula (LC4) is preferably 1 to 50 mol % and more preferably 1 to 10 mol % with respect to the total mass of the liquid crystal polymer.

The liquid crystal polymer may have a particle shape.
In a case where the polymer layer contains a liquid crystal polymer, it is preferable that the polymer layer further contains the specific polyarylate.
An average particle diameter of the particle-shaped liquid crystal polymer is preferably 1 to 30 μm, more preferably 3 to 25 μm, and still more preferably 5 to 20 μm.
The average particle diameter can be measured, for example, with a dynamic scattering particle size distribution analyzer.

A melting point of the liquid crystal polymer is preferably 300° C. or higher, more preferably 305° C. or higher, and still more preferably 310° C. or higher. The upper limit thereof is preferably 350° C. or lower, more preferably 345° C. or lower, and still more preferably 340° C. or lower.
The melting point can be measured with a differential scanning calorimeter manufactured by Hitachi High-Tech Science Corporation or the like in accordance with the test methods of ISO 11357 and ASTM D3418.

The liquid crystal polymer may be used alone or in combination of two or more kinds thereof.
A content of the liquid crystal polymer is preferably 20% to 95% by mass, more preferably 30% to 85% by mass, and still more preferably 40% to 75% by mass with respect to the total mass of the polymer layer.

### Other Polymers

The polymer layer may contain other polymers in addition to the specific polyarylate.
Examples of the other polymers include a polyarylate other than the specific polyarylate, a polymer having a repeating unit derived from styrene, polytetrafluoroethylene, polyethylene, polypropylene, and a cycloolefin polymer.
The polyarylate other than the specific polyarylate may have a crosslinking structure. As the crosslinking structure, a crosslinking structure which can be included in the specific polyarylate is preferable.

A thickness of the polymer layer is preferably 1 to 100 μm and more preferably 2 to 60 μm.
In the present specification, in a case where the laminate includes a single polymer layer, the above-described thickness of the polymer layer is a thickness of the single polymer layer. In addition, in a case where the laminate includes a plurality of polymer layers, the above-described thickness of the polymer layer is a thickness of each single polymer layer, and is not the total thickness of the plurality of polymer layers.
In addition, in a case where the laminate includes a plurality of polymer layers, the total thickness of the plurality of polymer layers is preferably 50 to 500 μm and more preferably 50 to 200 μm.

### Suitable Aspect of Laminate

In a case where the laminate includes a single polymer layer, the laminate is preferably a laminate including the copper layer and the single polymer layer in this order (hereinafter, also referred to as “laminate X”). In other words, the laminate X has a configuration in which the single polymer layer is provided on the copper layer, and has a two-layer structure as a whole. The single polymer layer in the laminate X contains the specific polyarylate.

Examples of a suitable aspect of the laminate X include an aspect X.
Aspect X: a laminate including a copper layer and a single polymer layer, in which the single polymer layer contains the specific polyarylate
In addition, it is also preferable that at least one of the fact that the single polymer layer further contains a liquid crystal polymer or the fact that the specific polyarylate has a crosslinking structure is satisfied, and it is more preferable that the single polymer layer contains a liquid crystal polymer and the specific polyarylate has a crosslinking structure.

In a case where the laminate includes a multi-polymer layer, the laminate is preferably a laminate including the copper layer and the multi-polymer layer in this order (hereinafter, also referred to as “laminate Y”). In other words, the laminate Y has a configuration in which the multi-polymer layer is provided on the copper layer, and has a multilayer structure of three or more layers as a whole. Among the multi-polymer layers in the laminate Y, at least a polymer layer (first polymer layer) in direct contact with the copper layer contains the specific polyarylate.

Examples of a suitable aspect of the laminate Y include an aspect Y1 to an aspect Y8.
The aspect Y1 to the aspect Y5 are aspects in which two polymer layers are provided, and the aspect Y6 to the aspect Y8 are aspects in which three polymer layers are provided. Examples of an aspect having four or more polymer layers include an aspect in which each polymer layer constituting the aspect Y1 to the aspect Y8 is laminated on the laminate Y of the aspect Y1 to the aspect Y8.
Aspect Y1: a laminate including a copper layer, a first polymer layer, and a second polymer layer in this order, in which the first polymer layer contains the specific polyarylate, and the second polymer layer contains a liquid crystal polymer
Aspect Y2: a laminate including a copper layer, a first polymer layer, and a second polymer layer in this order, in which the first polymer layer contains the specific polyarylate and a first liquid crystal polymer, and the second polymer layer contains a second liquid crystal polymer;
the first liquid crystal polymer and the second liquid crystal polymer in the aspect Y2 may be the same or different from each other
Aspect Y3: a laminate including a copper layer, a first polymer layer, and a second polymer layer in this order, in which the first polymer layer contains a first specific polyarylate having a crosslinking structure and a first liquid crystal polymer, and the second polymer layer contains a second specific polyarylate having no crosslinking structure and a second liquid crystal polymer;
the first liquid crystal polymer and the second liquid crystal polymer in the aspect Y3 may be the same or different from each other
Aspect Y4: a laminate including a copper layer, a first polymer layer, and a second polymer layer in this order, in which the first polymer layer contains a specific polyarylate which may have a crosslinking structure, and a liquid crystal polymer, and the second polymer layer contains other polymers different from both the specific polyarylate and the liquid crystal polymer (polymer which does not correspond to any of the specific polyarylate and the liquid crystal polymer)
Aspect Y5: a laminate including a copper layer, a first polymer layer, and a second polymer layer in this order, in which the first polymer layer contains a first specific polyarylate and a first liquid crystal polymer, and the second polymer layer contains a second specific polyarylate which may have a crosslinking structure, and a second liquid crystal polymer;
the first specific polyarylate and the second specific polyarylate in the aspect Y5 may be the same or different from each other;
the first liquid crystal polymer and the second liquid crystal polymer in the aspect Y5 may be the same or different from each other

Aspect Y6: a laminate including a copper layer, a first polymer layer, a second polymer layer, and a third polymer layer in this order, in which the first polymer layer contains a first specific polyarylate, the second polymer layer contains a liquid crystal polymer, and the third polymer layer contains a second specific polyarylate;
the first specific polyarylate and the second specific polyarylate in the aspect Y6 may be the same or different from each other
Aspect Y7: a laminate including a copper layer, a first polymer layer, a second polymer layer, and a third polymer layer in this order, in which the first polymer layer contains a first specific polyarylate and a first liquid crystal polymer, the second polymer layer contains a second liquid crystal polymer, and the third polymer layer contains a second specific polyarylate and a third liquid crystal polymer;
the first specific polyarylate and the second specific polyarylate in the aspect Y7 may be the same or different from each other;
the first to third liquid crystal polymers in the aspect Y7 may be the same or different from each other
Aspect Y8: a laminate including a copper layer, a first polymer layer, a second polymer layer, and a third polymer layer in this order, in which the first polymer layer contains a first specific polyarylate having a crosslinking structure, and a first liquid crystal polymer, the second polymer layer contains a second liquid crystal polymer, and the third polymer layer contains a second specific polyarylate having a crosslinking structure, and a third liquid crystal polymer;
the first specific polyarylate and the second specific polyarylate in the aspect Y8 may be the same or different from each other;
the first to third liquid crystal polymers in the aspect Y8 may be the same or different from each other.

### Production Method of Specific Polyarylate

A production method of the specific polyarylate is not particularly limited, and a known production method may be used.
The production method of the specific polyarylate preferably includes a step of mixing a mixture containing an alkaline aqueous solution of dihydric phenol and an organic solvent with solid 4,4′-biphenyldicarbonyl chloride. Among these, the production method of the specific polyarylate more preferably includes a step of adding the solid 4,4′-biphenyldicarbonyl chloride to the mixture containing an alkaline aqueous solution of dihydric phenol and an organic solvent while stirring the mixture.
In the present specification, the “solid 4,4′-biphenyldicarbonyl chloride” means a solid 4,4′-biphenyldicarbonyl chloride itself, not in a state mixed with an organic solvent (not in a solution state or slurry state).

### Method A

The production method of the specific polyarylate may include a method A.
In particular, in a case where a divalent carboxylic acid halide is not dissolved in an organic solvent of an organic phase or has low solubility, the method A is an effective method.

In the method A, as a water phase, an alkaline aqueous solution of dihydric phenol is prepared, and then a polymerization catalyst is added thereto.
In this case, in the alkaline aqueous solution of dihydric phenol, the dihydric phenol or a phenoxide thereof may not be completely dissolved. Furthermore, as an organic phase, only an organic solvent which is incompatible with water and dissolves the specific polyarylate is mixed with the above-described alkaline aqueous solution, and suspended by stirring. Next, a solid divalent carboxylic acid halide such as a powder is added thereto, and a polymerization reaction is carried out.

The method A has three advantages.
The first advantage is that, since the divalent carboxylic acid halide is not made into a solution or a solvent suspension in advance, hydrolysis can be suppressed until being mixed with the alkaline aqueous solution of dihydric phenol.
The second advantage is that, since the solvent suspension is not handled, it is not required to perform a complicated operation of transferring the solvent suspension in order to mix the solvent suspension with the alkaline aqueous solution.
The third advantage is that an organic solvent can be saved. In order to avoid treating the divalent carboxylic acid halide as a solvent suspension, it is conceivable to dilute the divalent carboxylic acid halide with a large amount of a solvent to form a solution. On the other hand, in the method A of adding the solid divalent carboxylic acid halide, since it is not necessary to completely dissolve the divalent carboxylic acid halide itself, the amount of the organic solvent used can be reduced. As a result, production efficiency is improved, and the organic solvent can be saved.
In addition, the polymerization catalyst may be added to the water phase in advance, or may be added to the organic phase.
Examples of alkali used for preparing the dihydric phenol aqueous solution include sodium hydroxide, potassium hydroxide, and lithium hydroxide. An amount of the alkali used is generally 2 to 5 times the number of moles in the dihydric phenol, that is, 1 to 2.5 equivalents with respect to the hydroxyl group.

In the method A in the production method of the specific polyarylate, from the viewpoint of enhancing characteristics of the obtained specific polyarylate, it is preferable to use, as the dihydric phenol component, a monomer from which the above-described repeating unit I is derived.

From the viewpoint of workability during the production, it is preferable that the solid 4,4′-biphenyldicarbonyl chloride does not contain an organic solvent.
In a case where 4,4′-biphenyldicarbonyl chloride contains an organic solvent, a content of the organic solvent with respect to the total amount of the solid 4,4′-biphenyldicarbonyl chloride and the organic solvent is preferably 20% by mass or less, more preferably 10% by mass or less, and still more preferably 5% by mass or less.

In the interfacial polymerization of the production method of the specific polyarylate, from the viewpoint of enhancing characteristics of the obtained specific polyarylate and controlling the molecular weight during polymerization, it is preferable to use a compound represented by Formula (S) together with the dihydric phenol.

H—O—R^{a} (S)

In Formula (S), R^{a} represents a monovalent organic group.
As the monovalent organic group, an alkyl group or an aryl group is preferable.
The alkyl group represented by R^{a} may be linear or branched.
The number of carbon atoms in the alkyl group (in a case of having a substituent, the number of carbon atoms including the substituent) is preferably 1 to 13, more preferably 1 to 8, still more preferably 1 to 6, and particularly preferably 1 to 3.
The number of carbon atoms in the aryl group represented by R^{a} (in a case of having a substituent, the number of carbon atoms including the substituent) is preferably 6 to 30, more preferably 6 to 25, still more preferably 6 to 20, particularly preferably 6 to 15, and most preferably 6 to 12. As the aryl group represented by R^{a}, a phenyl group is preferable.
Examples of the compound represented by Formula (S) include monohydric phenol and monohydric alcohol, which are used in a method C described later.

In the production method of the specific polyarylate, post treatment in the method for producing the above-described polymer may be carried out.

Examples of the production method of the specific polyarylate include a production method of polycondensing a monomer from which the repeating unit I is derived, a monomer from which the repeating unit II is derived, and as necessary, other monomers by a conventional method.

Examples of a method of polycondensing the above-described monomers include a method of polycondensing by an interfacial polymerization method, a solution polymerization method, and the like; and an interfacial polymerization method is preferable.
The interfacial polymerization method is a polymerization method in which a divalent carboxylic acid halide dissolved in an organic solvent which is incompatible with water is mixed with a dihydric phenol dissolved in an alkaline aqueous solution to obtain polyester. Examples of a document relating to the interfacial polymerization method include W. M. EARECKSON, J. Poly. Sci., XL399, 1959 and JP1975-001959B (JP-S40-001959B).
A reaction in the interfacial polymerization method is faster than that in the solution polymerization method, so that hydrolysis of the acid halide can be suppressed, and as a result, a specific polyarylate having a high molecular weight can be obtained.
Specifically, as a water phase, an alkaline aqueous solution of dihydric phenol is prepared, and then a polymerization catalyst is added thereto. On other hand, as an organic phase, a halide of divalent carboxylic acid is dissolved in an organic solvent which is incompatible with water and dissolves the specific polyarylate, the solution is mixed with the above-described alkaline aqueous solution as the water phase, and a polymerization reaction is carried out with stirring at a temperature of preferably 50° C. or lower for 1 to 8 hours. All of the divalent carboxylic acid halides may not be dissolved in the organic phase.

### Method B

In the above-described production method of the specific polyarylate, a method B may be used.
As an organic phase, an organic solvent which is incompatible with water and dissolves the specific polyarylate is mixed with divalent carboxylic acid halide, and stirred to obtain a suspension. On the other hand, as a water phase, an alkaline aqueous solution of dihydric phenol is prepared in another container, and then a polymerization catalyst is added thereto. The obtained water phase is added to the above-described suspension to carry out a polymerization reaction.
In a case where the divalent carboxylic acid halide is prepared as an organic solvent suspension in advance by the above-described method B, reproducibility of the polymerization step may be improved. In addition, as compared with a case of adding the solvent suspension of the divalent carboxylic acid halide to the alkaline aqueous solution of the dihydric phenol, which is a reverse procedure, since the above-described method B does not include a solution transfer step of the solvent suspension, complexity of the operation is reduced, and there is less concern about hydrolysis of the divalent carboxylic acid halide in the solution transfer step.

### Method C

In the above-described production method of the specific polyarylate, a method C may be used.
As a method of a general interfacial polymerization method described above, as a water phase, an alkaline aqueous solution of dihydric phenol is prepared, and then a polymerization catalyst is added thereto. On the other hand, as an organic phase, a solution or a solvent suspension of divalent carboxylic acid halide is prepared, and then added to the above-described alkaline aqueous solution as the water phase to carry out a polymerization reaction.

In the interfacial polymerization, from the viewpoint of controlling the molecular weight of the specific polyarylate, a terminal blocking agent may be used during the polymerization. In addition, from the viewpoint of controlling characteristics of the specific polyarylate, it is preferable that the terminal of the above-described specific polyarylate is sealed with a monohydric phenol, a monovalent acid chloride, a monohydric alcohol, a monovalent carboxylic acid, or the like.
Examples of the monohydric phenol include phenol, o-cresol, m-cresol, p-cresol, p-tert-butylphenol, o-phenylphenol, m-phenylphenol, p-phenylphenol, o-methoxyphenol, m-methoxyphenol, p-methoxyphenol, 2,3,5-trimethylphenol, 2,3,6-trimethylphenol, 2,3-xylenol, 2,4-xylenol, 2,5-xylenol, 2,6-xylenol, 3,4-xylenol, 3,5-xylenol, 2-phenyl-2-(4-hydroxyphenyl)propane (also described as “p-(α-cumyl)phenol)”), 2-phenyl-2-(2-hydroxyphenyl)propane, and 2-phenyl-2-(3-hydroxyphenyl)propane.
Examples of the monovalent acid chloride include benzoyl chloride, methanesulfonyl chloride, phenyl chlorocarbonate, acetyl chloride, and lauroyl chloride.
Examples of the monohydric alcohol include methanol, ethanol, n-propanol, isopropanol, n-butanol, 2-butanol, pentanol, hexanol, dodecyl alcohol, stearyl alcohol, benzyl alcohol, and phenethyl alcohol.
Examples of the monovalent carboxylic acid include acetic acid, propionic acid, octanoic acid, cyclohexanecarboxylic acid, benzoic acid, toluic acid, phenylacetic acid, p-tert-butylbenzoic acid, and p-methoxyphenylacetic acid.
Among these, the terminal is blocked with preferably the monohydric phenol or the monovalent acid chloride, and more preferably p-tert-butylphenol, 2,3,5-trimethylphenol, 2,3,6-trimethylphenol, benzoyl chloride, or acetyl chloride.

Examples of the polymerization catalyst of the interfacial polymerization include quaternary ammonium salts such as tributylbenzylammonium halide, tetrabutylammonium halide, trimethylbenzylammonium halide, and tricthylbenzylammonium halide; and quaternary phosphonium salts such as tributylbenzylphosphonium halide, tetrabutylphosphonium halide, trimethylbenzylphosphonium halide, and tricthylbenzylphosphonium halide.
Among these, from the viewpoint of easily promoting the polymerization, tributylbenzylammonium halide, tetrabutylammonium halide, tributylbenzylphosphonium halide, or tetrabutylphosphonium halide is preferable.

Examples of the organic solvent of the organic phase in the interfacial polymerization include chlorine-based solvents such as dichloromethane, 1,2-dichloroethane, chloroform, carbon tetrachloride, chlorobenzene, 1,1,2,2-tetrachloroethane, 1,1,1-trichlorocthane, o-dichlorobenzene, m-dichlorobenzene, and p-dichlorobenzene; aromatic hydrocarbons such as toluene, benzene, xylene, and anisole; and tetrahydrofuran.
Among these, dichloromethane or o-dichlorobenzene is preferable.
In a case where the divalent carboxylic acid halide is insoluble in the organic solvent of the organic phase, or has low solubility in the organic solvent of the organic phase, another organic solvent can also be used. The organic solvent of the organic phase is preferably an organic solvent which is insoluble in water. In addition, for the purpose of improving the solubility of the divalent carboxylic acid halide in the organic phase, or for the purpose of increasing the efficiency of the polymerization reaction, suppressing the hydrolysis of the divalent carboxylic acid halide, and obtaining a specific polyarylate with a desired molecular weight, a part or all of the organic phase can be replaced with an organic solvent which also has solubility in water.
Examples of the organic solvent which is effective to improve the solubility of the divalent carboxylic acid halide in the organic phase include tetrahydrofuran, N,N-dimethylacetamide (DMAc), N-methyl-2-pyrrolidone (NMP), dimethylsulfoxide (DMSO), 1,4-dioxane, and 1,3-dioxolane.
From the viewpoint of productivity, it is preferable that a concentration of the polymer in the organic solvent of the organic phase is high. The content of the specific polyarylate in the organic phase is preferably 2% by mass or more, more preferably 6% by mass or more, and still more preferably 10% by mass or more with respect to the total mass of the organic phase. The upper limit thereof is preferably 50% by mass or less with respect to the total mass of the organic phase.
In addition, the content of the specific polyarylate in the water phase and the organic phase is preferably 1% by mass or more, more preferably 3% by mass or more, and still more preferably 5% by mass or more with respect to the total mass of the water phase and the organic phase. The upper limit thereof is preferably 50% by mass or less with respect to the total mass of the water phase and the organic phase.

Acetic acid is added to the specific polyarylate solution obtained after the polymerization to terminate the polymerization, and then the specific polyarylate solution is repeatedly stirred and washed with water to remove ionic components such as sodium ions, potassium ions, lithium ions, chloride ions, and polymerization catalyst, which are contained in the specific polyarylate solution. The water used for washing may be acidic or basic, and the washing is repeatedly performed until the washing waste water is neutral.

By adding dropwise the obtained specific polyarylate solution to a poor solvent, the specific polyarylate as a solid content is precipitated. A concentration of solid contents of the specific polyarylate solution is preferably 7% by mass or less. In addition, it is preferable that the volume of the poor solvent is 3 times or more the volume of the polymer solution. Examples of the poor solvent include methanol, ethanol, isopropyl alcohol, acetone, acetonitrile, and hexane.

By adding the specific polyarylate solution to the poor solvent, it is possible to reduce residual monomers, the alkali, and impurities derived from the polymerization catalyst, which are contained in the specific polyarylate. In order to reduce the content of the residual monomers and the impurities, it is particularly preferable that the immersion time in the poor solvent after the precipitation treatment in the poor solvent is 1 minute or longer. In addition, in a case where trimethylbenzylammonium halide, tricthylbenzylammonium halide, or the like, which has a relatively low polymerization activity, is used as the polymerization catalyst, it is preferable that the immersion time is 3 minutes or longer. In order to reduce the residual monomers and the impurities, the above-described operation of dissolving the obtained specific polyarylate in a solvent again and adding the solution to the poor solvent for precipitation may be repeated.

In a case of producing the above-described specific polyarylate, impurities insoluble in tetrahydrofuran or dichloromethane may be generated. One of causes is considered to be that 4,4′-biphenyldicarbonyl chloride or the like is used for introducing the repeating unit represented by Formula (II) described above. That is, it is considered that, in a case where 4,4′-biphenyldicarboxylic acid or 4-(4-carboxyphenyl)-benzoyl chloride, that is an impurity which can be contained in the 4,4′-biphenyldicarbonyl chloride, is brought into the production process of the above-described specific polyarylate, as shown in the following scheme, an acid anhydride compound is formed as the insoluble impurity.
In addition, during the polymerization reaction of the production process, 4,4′-biphenyldicarboxylic acid or 4-(4-carboxyphenyl)-benzoyl chloride may be generated, and then as shown in the following scheme, an acid anhydride compound may be formed.

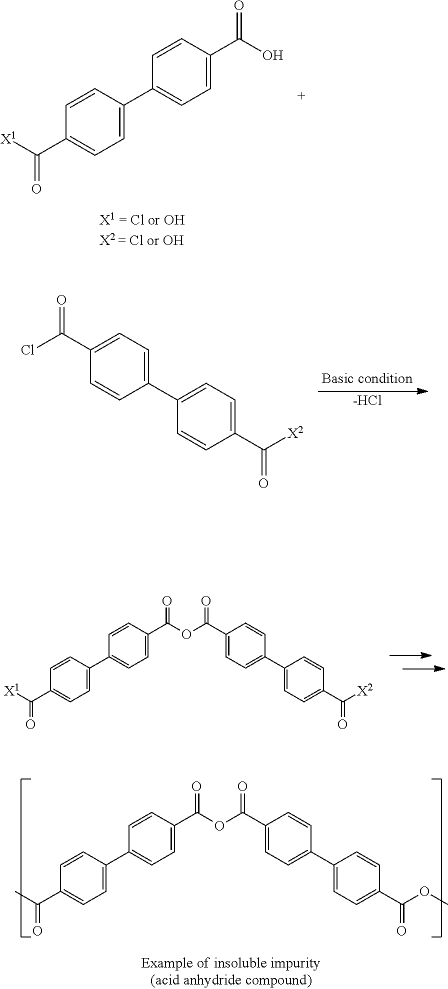

It is preferable that the polymer layer does not contain such insoluble impurities. Examples of a method of obtaining a specific polyarylate containing no insoluble impurities include a method in which a solution containing the polymer and the insoluble impurities is treated with various adsorbents to remove the insoluble impurities.
In addition, for the purpose of suppressing the generation of insoluble impurities, it is preferable to use 4,4′-biphenyldicarbonyl chloride containing less 4,4′-biphenyldicarboxylic acid or 4-(4-carboxyphenyl)-benzoyl chloride as an impurity. Each content of 4,4′-biphenyldicarboxylic acid and 4-(4-carboxyphenyl)-benzoyl chloride in the 4,4′-biphenyldicarbonyl chloride is preferably 5% by mass or less, more preferably 1% by mass or less, still more preferably 0.5% by mass or less, particularly preferably 0% by mass.

### Manufacturing Method of Laminate

Examples of a manufacturing method of the laminate include a known manufacturing method.
The manufacturing method of the laminate may be a manufacturing method of a laminate, including a step of applying a composition for forming a polymer layer onto a copper layer to form a polymer layer.
In a case where the laminate includes a single polymer layer, it is preferable that the manufacturing method of the laminate includes a step of applying a composition for forming a first polymer layer onto a copper layer to form a first polymer layer.
In a case where the laminate includes a multi-polymer layer, it is preferable that the manufacturing method of the laminate includes a step of applying a composition for forming a first polymer layer onto a copper layer to form a first polymer layer, and a step of applying a composition for forming a second polymer layer onto the obtained first polymer layer to form a second polymer layer. In addition, it is also preferable that the manufacturing method of the laminate includes a step of simultaneously applying the composition for forming a first polymer layer and the composition for forming a second polymer layer onto the copper layer to form the first polymer layer and the second polymer layer in multiple layers.
In a case where the laminate includes three or more polymer layers, the number of coating times may be appropriately adjusted according to the number of desired polymer layers. In a case of forming the multi-polymer layer, either sequential multilayer coating or simultaneous multilayer coating may be adopted.
In addition, a drying treatment or the like may be performed after the application as necessary.

It is also preferable that the manufacturing method of the laminate includes a step of melting a polymer (for example, the specific polyarylate, the liquid crystal polymer, and the like) to form a polymer layer, and a step of bonding the obtained polymer layer and a copper layer.
In addition, a composition for forming a polymer layer may be further applied onto the above-described polymer layer formed into a film to form a single or multi-polymer layer, or a composition for forming a polymer layer may be further applied onto the copper layer to form a single or multi-polymer layer. In a case where the polymer layer is formed on the formed polymer layer formed into a film or on the copper layer, the polymer layer may be formed before or after the bonding.
The above-described step of forming the polymer layer preferably includes a step of kneading a polymer (for example, the specific polyarylate polymer, the liquid crystal polymer, and the like) to obtain pellets and a step of forming a film using the obtained pellets.
Examples of the step of forming the polymer layer include steps described in WO2022/138618A.

### Composition for Forming Polymer Layer

The composition for forming a polymer layer is a composition used for forming the polymer layer.
The composition for forming a polymer layer preferably contains various components (for example, the specific polyarylate and the like) which can be contained in the polymer layer, and a solvent.
Furthermore, the composition for forming a polymer layer preferably contains a crosslinking agent and a curing agent.
In a case where the composition for forming a polymer layer contains a crosslinking agent and a curing agent, the polymer (for example, the specific polyarylate and the like) in the formed polymer layer has a crosslinking structure.

Examples of the solvent include chlorine-based solvents such as dichloromethane, 1,2-dichloroethane, chloroform, carbon tetrachloride, chlorobenzene, 1,1,2,2-tetrachloroethane, 1,1,1-trichloroethane, o-dichlorobenzene, and m-dichlorobenzene; aromatic hydrocarbons such as toluene, benzene, and xylene; N-methyl-2-pyrrolidone (NMP), N,N-dimethylacetamide (DMAc), 1,4-dioxane, and tetrahydrofuran.
The solvent may be used alone or in combination of two or more kinds thereof.

Examples of the crosslinking agent include aliphatic polyfunctional epoxy compounds such as 1,5-hexadiene di-epoxy and 1,4-butanediol diglycidyl ether; aromatic polyfunctional epoxy compounds such as 2,2-bis(4-glycidyloxyphenyl)propane and N,N-diglycidyl-4-glycidyloxyaniline; and heterocycle-containing polyfunctional epoxy compounds such as triglycidyl isocyanurate.
The crosslinking agent may be used alone or in combination of two or more kinds thereof.
A content of the crosslinking agent is preferably 0.1 to 10% by mass and more preferably 1% to 5% by mass with respect to the total solid content of the composition for forming a polymer layer.

Examples of the curing agent include imidazoles such as 2-methylimidazole, 2-ethyl-4-methylimidazole, and 2-phenylimidazole; tertiary amines such as 4-dimethylaminopyridine, benzyldimethylamine, 2-(dimethylaminomethyl)phenol, and 2,4,6-tris(dimethylaminomethyl)phenol; and organic phosphines such as triphenylphosphine and tributylphosphine.
The curing agent may be used alone or in combination of two or more kinds thereof.
A content of the curing agent is preferably 0.01 to 10% by mass and more preferably 0.1% to 5% by mass with respect to the total solid content of the composition for forming a polymer layer.

### Applications

The laminate can be suitably used for a high-frequency circuit board, and it is preferable to use the laminate as a laminate for a high-frequency circuit board.
The high-frequency circuit board is a circuit board which can operate even in a high-frequency band (particularly, 5G). The high-frequency band is preferably a band of 1 GHz or more, more preferably a band of 3 GHz or more, and still more preferably a band of 5 GHz or more. The upper limit thereof is preferably a band of 100 GHz or less.
Since the laminate has excellent low dielectric characteristics, low water absorption, and adhesiveness, a high-frequency circuit board having a small transmission loss even in the high-frequency band, low water absorption, and excellent adhesiveness can be obtained.

### EXAMPLES

Hereinafter, the present invention will be described in more detail based on Examples, but the present invention is not limited thereto. In structural formulae shown below, Me represents a methyl group.

### Various Components

### Polymer

### Specific Polyarylate P-01

A specific polyarylate P-01 was prepared according to the following scheme.

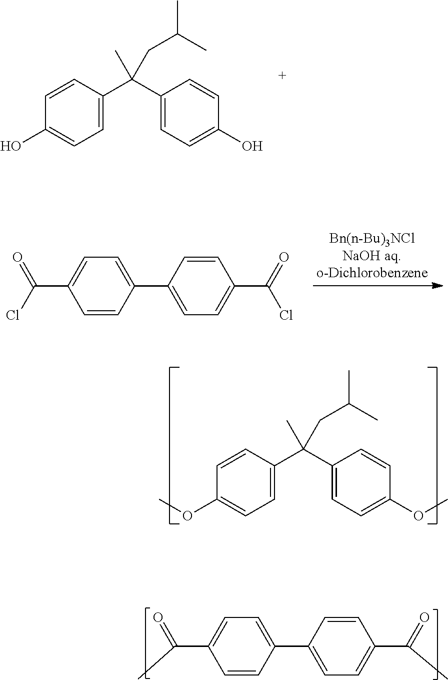

2,2-bis(4-hydroxyphenyl)-4-methylpentane (manufactured by Honshu Chemical Industry Co., Ltd.; 11.4493 g), 2,3,5-trimethylphenol (manufactured by Tokyo Chemical Industry Co., Ltd.; 0.1750 g), sodium hydrosulfite (manufactured by FUJIFILM Wako Pure Chemical Corporation; 0.0572 g), and water (230 mL) were charged into a reaction container equipped with a stirrer to obtain a suspension. Sodium hydroxide (manufactured by FUJIFILM Wako Pure Chemical Corporation; 4.8378 g), benzyltributylammonium chloride (manufactured by FUJIFILM Wako Pure Chemical Corporation; 0.1981 g), and water (150 mL) were added to the suspension with stirring at a temperature of room temperature (20° C.), and the mixture was stirred for 30 minutes under a nitrogen atmosphere to obtain a solution in which the solids were mostly dissolved (there was some turbidity). o-dichlorobenzene (manufactured by FUJIFILM Wako Pure Chemical Corporation; 210 mL) was added to the aqueous solution, the mixture was stirred for 30 minutes under a nitrogen atmosphere, and then 4,4′-biphenyldicarbonyl chloride (manufactured by Tokyo Chemical Industry Co., Ltd.; 12.0000 g) as powder was added thereto. After completion of the addition, the temperature was set to room temperature (20° C.), and the mixture was stirred for 4 hours under a nitrogen atmosphere to proceed a reaction. The solution after the polymerization was diluted with o-dichlorobenzene (300 mL), and the water phase was removed. After washing with a dilute acetic acid solution and ion exchange water, the resultant was poured into methanol (manufactured by FUJIFILM Wako Pure Chemical Corporation) to precipitate a polymer. The precipitated polymer was filtered, and dried at 50° C. The polymer was re-dissolved in 900 mL of tetrahydrofuran (manufactured by FUJIFILM Wako Pure Chemical Corporation), and poured into methanol to precipitate the polymer. The precipitated polymer was filtered, washed with methanol, and then dried at 50° C. to obtain a white specific polyarylate P-01 (17.8 g). A weight-average molecular weight (Mw) of the specific polyarylate P-01, which was determined as a polystyrene-equivalent molecular weight by gel permeation chromatography (GPC; using tetrahydrofuran as an eluent), was 120,000.
The above-described method is a case where 4,4′-biphenyldicarbonyl chloride is added as a powder, and corresponds to the method A.

### Specific Polyarylate P-02

A specific polyarylate P-02 was prepared according to the following scheme.

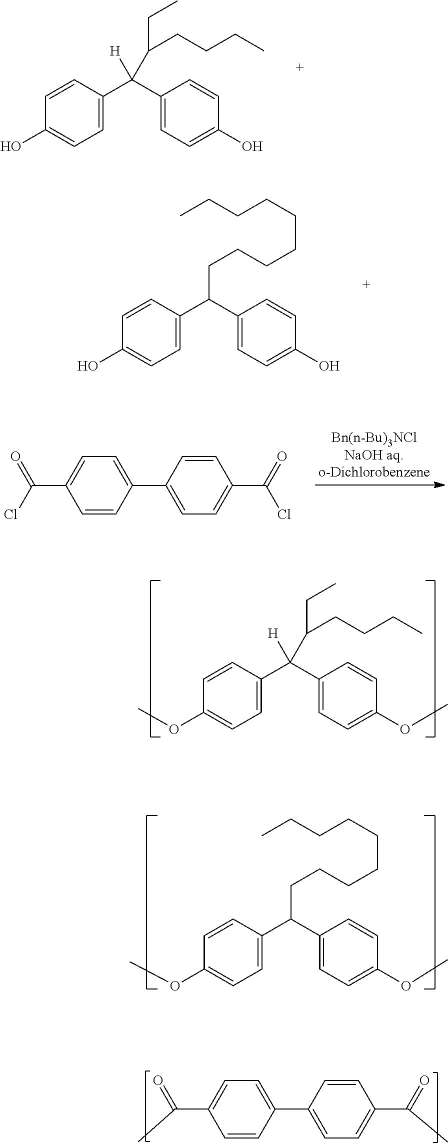

4,4′-(2-ethylhexylidene)diphenol (manufactured by Honshu Chemical Industry Co., Ltd.; 11.3740 g), 4,4′-decylidenebisphenol (manufactured by Honshu Chemical Industry Co., Ltd.; 1.3826 g), 2,3,5-trimethylphenol (manufactured by Tokyo Chemical Industry Co., Ltd.; 0.1757 g), sodium hydrosulfite (manufactured by FUJIFILM Wako Pure Chemical Corporation; 0.0515 g), and water (240 mL) were charged into a reaction container equipped with a stirrer to obtain a suspension. Sodium hydroxide (manufactured by FUJIFILM Wako Pure Chemical Corporation; 4.8323 g), benzyltributylammonium chloride (manufactured by FUJIFILM Wako Pure Chemical Corporation; 0.1783 g), and water (160 mL) were added to the suspension with stirring at a temperature of room temperature (20° C.), and the mixture was stirred for 30 minutes under a nitrogen atmosphere to obtain a solution in which the solid contents were mostly dissolved (there was some turbidity). o-dichlorobenzene (manufactured by FUJIFILM Wako Pure Chemical Corporation; 220 mL) was added to the aqueous solution, the mixture was stirred for 30 minutes under a nitrogen atmosphere, and then 4,4′-biphenyldicarbonyl chloride (manufactured by Tokyo Chemical Industry Co., Ltd.; 12.0000 g) as powder was added thereto. After completion of the addition, the temperature was set to room temperature (20° C.), and the mixture was stirred for 4 hours under a nitrogen atmosphere to proceed a reaction. The solution after the polymerization was diluted with o-dichlorobenzene (300 mL), and the water phase was removed. After washing with a dilute acetic acid solution and ion exchange water, the resultant was poured into methanol (manufactured by FUJIFILM Wako Pure Chemical Corporation) to precipitate a polymer. The precipitated polymer was filtered, and dried at 50° C. The polymer was re-dissolved in 900 mL of tetrahydrofuran (manufactured by FUJIFILM Wako Pure Chemical Corporation), and poured into methanol to precipitate the polymer. The precipitated polymer was filtered, washed with methanol, and then dried at 50° C. to obtain a white specific polyarylate P-02 (17.5 g). A weight-average molecular weight (Mw) of the specific polyarylate P-02, which was determined as a polystyrene-equivalent molecular weight by gel permeation chromatography (GPC; using tetrahydrofuran as an eluent), was 130,000.
The above-described method is a case where 4,4′-biphenyldicarbonyl chloride is added as a powder, and corresponds to the method A.

### Specific Polyarylate P-03

A specific polyarylate P-03 was prepared according to the following scheme.

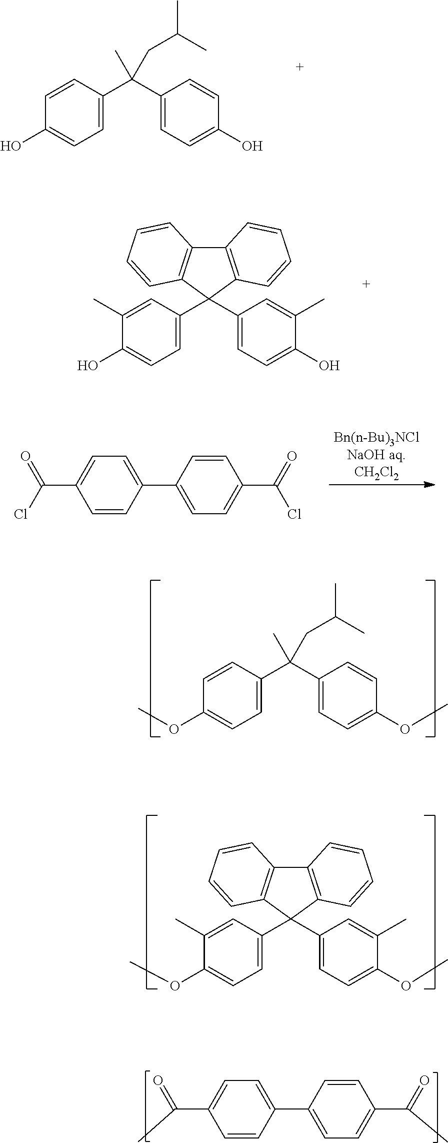

2,2-bis(4-hydroxyphenyl)-4-methylpentane (manufactured by Honshu Chemical Industry Co., Ltd.; 6.8697 g), 9,9-bis(4-hydroxy-3-methylphenyl)fluorene (manufactured by Tokyo Chemical Industry Co., Ltd.; 6.4109 g), 2,3,5-trimethylphenol (manufactured by Tokyo Chemical Industry Co., Ltd.; 0.1757 g), sodium hydrosulfite (manufactured by FUJIFILM Wako Pure Chemical Corporation; 0.0343 g), and water (244 mL) were charged into a reaction container equipped with a stirrer to obtain a suspension. Sodium hydroxide (manufactured by FUJIFILM Wako Pure Chemical Corporation; 4.8323 g), benzyltributylammonium chloride (manufactured by FUJIFILM Wako Pure Chemical Corporation; 0.1981 g), and water (163 mL) were added to the suspension with stirring at a temperature of room temperature (20° C.), and the mixture was stirred for 30 minutes under a nitrogen atmosphere to obtain a solution in which the solids were mostly dissolved (there was some turbidity). Dichloromethane (manufactured by FUJIFILM Wako Pure Chemical Corporation; 250 mL) was added to the aqueous solution, the mixture was stirred for 30 minutes under a nitrogen atmosphere, and then 4,4′-biphenyldicarbonyl chloride (manufactured by Tokyo Chemical Industry Co., Ltd.; 12.0000 g) as powder was added thereto. After completion of the addition, the temperature was set to room temperature (20° C.), and the mixture was stirred for 4 hours under a nitrogen atmosphere to proceed a reaction. The solution after the polymerization was diluted with dichloromethane (300 mL), and the water phase was removed. After washing with a dilute acetic acid solution and ion exchange water, the resultant was poured into methanol (manufactured by FUJIFILM Wako Pure Chemical Corporation) to precipitate a polymer. The precipitated polymer was filtered, and dried at 50° C. The polymer was re-dissolved in 900 mL of tetrahydrofuran (manufactured by FUJIFILM Wako Pure Chemical Corporation), and poured into methanol to precipitate the polymer. The precipitated polymer was filtered, washed with methanol, and then dried at 50° C. to obtain a white specific polyarylate P-03 (20.1 g). A weight-average molecular weight (Mw) of the specific polyarylate P-03, which was determined as a polystyrene-equivalent molecular weight by gel permeation chromatography (GPC; using tetrahydrofuran as an eluent), was 90,000.
The above-described method is a case where 4,4′-biphenyldicarbonyl chloride is added as a powder, and corresponds to the method A.

### Polyarylate CP-01

A polyarylate CP-01 was obtained with reference to JP2018-066018A.

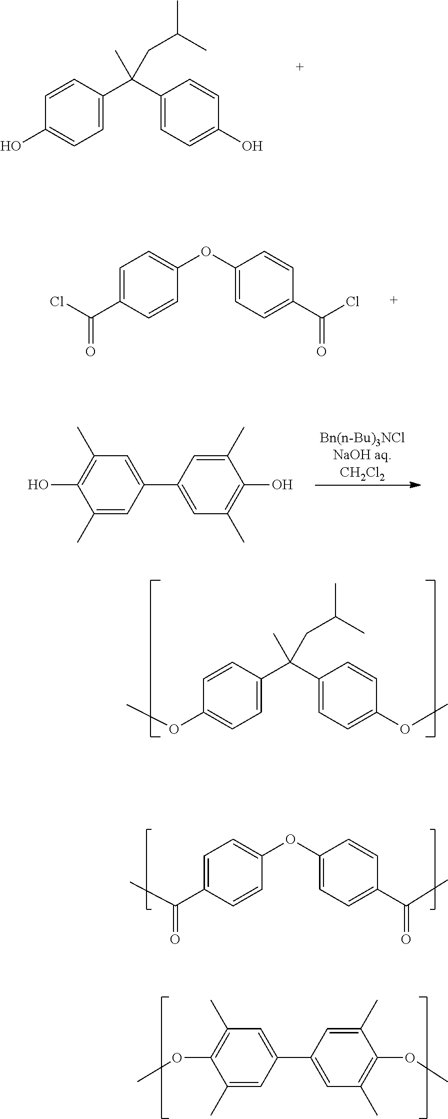

### Other Components

SEBS: styrene-based polymer, TUFTEC M1913, manufactured by Asahi Kasei Corporation
LCP: liquid crystal polymer particles, melting point: 320° C., synthesized based on Example 1 of JP2019-116586A
JER630: aminophenol-type epoxy resin (JER (registered trademark) 630), manufactured by Mitsubishi Chemical Corporation
2E4 MI: 2-ethyl-4-methylimidazole, IsoQure (registered trademark) IM 2E4 MI, manufactured by Tokyo Chemical Industry Co., Ltd.
DCM: dichloromethane

### Preparation of Composition for Forming Polymer Layer

As shown in the following table, predetermined amounts of various components were mixed to obtain each composition for forming a polymer layer.

TABLE 1

| Composition | Polymer | | Liquid crystal polymer | | Crosslinking agent | | Curing agent | | Solvent | |
|---|---|---|---|---|---|---|---|---|---|---|
| for forming | | Content | particles | | | Content | | Content | | Content |
| polymer | | % by | | Content | | % by | | % by | | % by |
| layer | Type | mass | Type | % by mass | Type | mass | Type | mass | Type | mass |
| 1 | P-01 | 5.00 | — | — | — | — | — | — | DCM | 95.00 |
| 2 | P-01 | 4.35 | LCP | 13.04 | — | — | — | — | DCM | 82.61 |
| 3 | P-01 | 4.14 | LCP | 13.10 | JER630 | 0.21 | 2E4MI | 0.02 | DCM | 82.53 |
| 4 | SEBS | 5.00 | — | — | — | — | — | — | DCM | 95.00 |
| 5 | P-02 | 4.35 | LCP | 13.04 | — | — | — | — | DCM | 82.61 |
| 6 | P-03 | 4.35 | LCP | 13.04 | — | — | — | — | DCM | 82.61 |
| 7 | CP-01 | 5.00 | — | — | — | — | — | — | DCM | 95.00 |

### Production of Liquid Crystal Polymer Layer 1

The LCP (liquid crystal polymer particles; 84.9 parts by mass), Novatec LD (low density polyethylene; 12.0 parts by mass) manufactured by Japan Polyethylene Corporation, Bond First (registered trademark) E (copolymer of ethylene and glycidyl methacrylate (E-GMA copolymer); 3.0 parts by mass) manufactured by Sumitomo Chemical Co., Ltd., and Irganox 1010 (hindered phenol-based thermal stabilizer; 0.1 parts by mass) manufactured by BASF SE were mixed with each other, and pelletized by kneading using an extruder. The polymer pelletized by kneading was dried at 80° C. using a dehumidifying hot air dryer having a dew point temperature of −45° C. for 12 hours to reduce the moisture content to 50 ppm or less.
The obtained pellets were supplied into a cylinder from the same supply port of a twin-screw extruder having a screw diameter of 50 mm, heated, and kneaded at 270° C. to 350° C., and a melted film-like liquid crystal polymer was discharged from a die having a die width of 750 mm and a slit spacing of 300 μm. An uneven thickness of the discharged film-like liquid crystal polymer in the width direction was improved by finely adjusting a clearance of the die lip portion. In this manner, a (film-like) liquid crystal polymer layer 1 having a thickness of 50 μm was obtained.

### Production of Laminate A (Examples 1 to 3, 8, and 9 and Comparative Example 1)

A composition for forming a polymer layer, which was used for forming a first layer shown in Table 2, was applied onto one surface of the obtained liquid crystal polymer layer 1 using an applicator while adjusting the flow rate so that the film thickness after drying was obtained as shown in Table 2. The coating film was dried under the conditions of 80° C. and 2 hours to obtain a laminate including a polymer layer A1 corresponding to the first layer shown in Table 2 on the liquid crystal polymer layer 1.
A surface of the polymer layer A1 in the obtained laminate, on a side opposite to the liquid crystal polymer layer 1, and a bonding surface of a copper foil (manufactured by FUKUDA METAL FOIL & POWDER CO., LTD., CF-T4X-SV-18, thickness: 18 μm, surface roughness Rz of bonding surface (treated surface): 0.85 μm) were bonded to each other, and then the laminate was pressure-bonded for 1 hour under conditions of 200° C. and 4 MPa using a hot press machine (manufactured by Toyo Seiki Seisaku-sho, Ltd.). As a result, a laminate including the copper foil, the polymer layer A1 (first layer), and the liquid crystal polymer layer 1 (second layer) in this order was obtained.
Furthermore, a composition for forming a polymer layer, which was used for forming a third layer shown in Table 2, was applied onto a surface of the liquid crystal polymer layer 1 in the obtained laminate, on a side opposite to the polymer layer A1, using an applicator. The coating film was dried under the conditions of 80° C. and 2 hours to produce a laminate A including a polymer layer A2 corresponding to the third layer shown in Table 2 on the liquid crystal polymer layer 1.
The laminate A included the copper foil, the polymer layer A1 (first layer), the liquid crystal polymer layer 1 (second layer), and the polymer layer A2 (third layer) in this order.

### Production of Laminate B (Examples 4 and 5)

A composition for forming a polymer layer, which was used for forming a first layer shown in Table 2, was applied onto a treated surface of a copper foil (manufactured by FUKUDA METAL FOIL & POWDER CO., LTD., CF-T4X-SV-18, thickness: 18 μm, surface roughness Rz of treated surface: 0.85 μm) while adjusting the flow rate so that the film thickness after drying was obtained as shown in Table 2. The coating film was dried under the conditions of 80° C. and 2 hours to obtain a laminate B including a polymer layer B corresponding to the first layer shown in Table 2 on the copper foil.
The laminate B included the copper foil and the polymer layer B (first layer) in this order.

### Production of Laminate C (Examples 6 and 7)

A composition for forming a polymer layer, which was used for forming a first layer shown in Table 2, was applied onto a treated surface of a copper foil (manufactured by FUKUDA METAL FOIL & POWDER CO., LTD., CF-T4X-SV-18, thickness: 18 μm, surface roughness Rz of treated surface: 0.85 μm) while adjusting the flow rate so that the film thickness after drying was obtained as shown in Table 2. The coating film was dried under the conditions of 80° C. and 2 hours to obtain a laminate including a polymer layer C1 corresponding to the first layer shown in Table 2 on the copper foil.
Furthermore, a composition for forming a polymer layer, which was used for forming a second layer shown in Table 2, was applied onto a surface of the polymer layer C1 in the obtained laminate, on a side opposite to the copper foil, using an applicator. The coating film was dried under the conditions of 80° C. and 2 hours to produce a laminate C including a polymer layer C2 corresponding to the second layer shown in Table 2 on the polymer layer C1.
The laminate C included the copper foil, the polymer layer C1 (first layer), and the polymer layer C2 (second layer) in this order.

### Evaluation

The copper foil in the laminates of Examples and Comparative Examples was removed by an etching treatment (immersed in a 40% by mass aqueous solution of iron (III) chloride (manufactured by Wako Pure Chemical Industries, Ltd.) for 6 hours), and then a sample for measuring dielectric characteristics and measuring water absorption rate was obtained.

### Dielectric Characteristics

Dielectric characteristics were evaluated by measuring a dielectric loss tangent using a resonance perturbation method at a frequency of 10 GHz.
A 10 GHz cavity resonator (CP531 manufactured by Kanto Electronics Application Development) was connected to a network analyzer (“E8363B” manufactured by Agilent Technology), the measurement sample was inserted into the cavity resonator, and a dielectric loss tangent of the laminate was measured and evaluated according to the following evaluation standard based on a change in resonance frequency after 96 hours and before the insertion in an environment of a temperature of 25° C. and a humidity of 60% RH.
4: dielectric loss tangent was less than 0.002.
3: dielectric loss tangent was 0.002 or more and 0.004 or less.
2: dielectric loss tangent was more than 0.004 and 0.006 or less.
1: dielectric loss tangent was more than 0.006.

### Water Absorption

The measurement sample (approximately 0.2 g) was cut out and infused with deionized water. After the infusing at 25° C. for 1 week, water droplets on the surface were wiped off, and a water absorption rate was measured by Karl Fischer vaporization method (measurement device: AQ-2250, vaporization device: AQS-225320, used reagent: AQUALITE RS-A (for general use), measurement temperature: 180° C., nitrogen gas flow rate: 200 mL/min) and evaluated according to the following evaluation standard.
4: water absorption rate was less than 0.04% by mass.
3: water absorption rate was 0.04% by mass or more and 0.1% by mass or less.
2: water absorption rate was more than 0.1% by mass and 0.2% by mass or less.
1: water absorption rate was more than 0.2% by mass.

### Adhesiveness to Copper Layer

Each of the laminates of Examples and Comparative Examples was cut into a strip shape of 1 cm×5 cm to produce a sample for evaluating adhesiveness. Adhesiveness (unit: kN/m) of the obtained evaluation sample was measured according to a method for measuring a peeling strength described in JIS C 6481. The peeling conditions were such that the copper foil was peeled off from the evaluation sample at a peeling rate of 50 mm/sec at an angle of 90° with respect to the evaluation sample. The measurement was carried out 5 times, and an arithmetic average value was obtained and evaluated according to the following evaluation standard.
4: peel strength was more than 15 kN/m.
3: peel strength was 10 KN/m or more and 15 kN/m or less.
2: peel strength was 7 kN/m or more and less than 10 kN/m.
1: peel strength was less than 7 kN/m.

The evaluation results are shown in Table 2.
The column of “Type” indicates whether the laminate corresponds to the above-described laminate A, the above-described laminate B, or the above-described laminate C.
The columns of “First layer”, “Second layer”, and “Third layer” in “Polymer layer” indicate the configuration of each laminate. That is, each laminate includes a copper layer, a first polymer layer, an optional second polymer layer, and an optional third polymer layer in this order. Specifically, the laminate of Example 1 includes a copper layer, a first polymer layer (layer derived from the composition 1 for forming a polymer layer), a second polymer layer (liquid crystal polymer layer 1), and a third polymer layer (layer derived from the composition 1 for forming a polymer layer) in this order.

TABLE 2

| | Laminate | | | | | | | | | | | | |
|---|---|---|---|---|---|---|---|---|---|---|---|---|---|
| | | | Polymer layer | | | | | | | | | | |
| | | | First layer | | Second layer | | | | Third layer | | | | |
| | | | Com- | | Com- | | | | Com- | | | | |
| | | | position | | position | | | | position | | | | |
| | | | for | | for | | | | for | | | | |
| | | | forming | Thick- | forming | Thick- | Liquid | | forming | Thick- | Dielectric | | |
| | | Copper | polymer | ness | polymer | ness | polymer | Thickness | polymer | ness | character- | Water | Adhesive- |
| | Type | layer | layer | μm | layer | μm | layer | μm | layer | μm | istics | absorption | ness |
| Example | A | Copper | 1 | 20 | — | — | 1 | 50 | 1 | 20 | 4 | 3 | 4 |
| 1 | | foil | | | | | | | | | | | |
| Example | A | Copper | 2 | 20 | — | — | 1 | 50 | 2 | 20 | 4 | 4 | 3 |
| 2 | | foil | | | | | | | | | | | |
| Example | A | Copper | 3 | 20 | — | — | 1 | 50 | 3 | 20 | 4 | 4 | 4 |
| 3 | | foil | | | | | | | | | | | |
| Example | B | Copper | 2 | 90 | — | — | — | — | — | — | 3 | 3 | 3 |
| 4 | | foil | | | | | | | | | | | |
| Example | B | Copper | 3 | 90 | — | — | — | — | — | — | 3 | 3 | 4 |
| 5 | | foil | | | | | | | | | | | |
| Example | C | Copper | 2 | 45 | 3 | 45 | — | — | — | — | 4 | 4 | 3 |
| 6 | | foil | | | | | | | | | | | |
| Example | C | Copper | 3 | 45 | 4 | 45 | — | — | — | — | 3 | 3 | 4 |
| 7 | | foil | | | | | | | | | | | |
| Example | A | Copper | 5 | 20 | — | — | 1 | 50 | 5 | 20 | 3 | 4 | 3 |
| 8 | | foil | | | | | | | | | | | |
| Example | A | Copper | 6 | 20 | — | — | 1 | 50 | 6 | 20 | 4 | 3 | 3 |
| 9 | | foil | | | | | | | | | | | |
| Compar- | A | Copper | 7 | 20 | — | — | 1 | 50 | 7 | 20 | 1 | 2 | 2 |
| ative | | foil | | | | | | | | | | | |
| Example | | | | | | | | | | | | | |
| 1 | | | | | | | | | | | | | |

From the results shown in the table, it was found that the laminate according to the embodiment of the present invention was excellent in all of low dielectric characteristics, low water absorption rate, and adhesiveness.
It was found that, in a case where the specific polyarylate included only the repeating unit represented by Formula (I-Aa) as the repeating unit I, the effect of the present invention was more excellent (Examples 2, 8, and 9).

What is claimed is:

1. A laminate comprising:
a copper layer; and
a polymer layer,
wherein the polymer layer contains a polyarylate, and
the polyarylate has at least one repeating unit I selected from the group consisting of a repeating unit represented by Formula (I-A), a repeating unit represented by Formula (I-B), and a repeating unit represented by Formula (I-C), and has a repeating unit II represented by Formula (II), 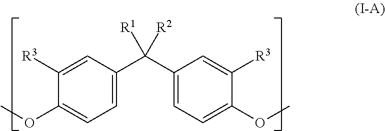
in Formula (I-A), R¹ represents a branched alkyl group having 4 or more carbon atoms,
R² represents a hydrogen atom, a linear alkyl group, or an aryl group which may have a substituent, and
R³ represents a hydrogen atom, an alkyl group, or an aryl group which may have a substituent,
provided that R¹ and R² are not bonded to each other to form a ring structure, 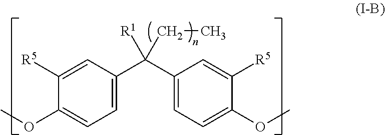
in Formula (I-B), R⁴ represents a hydrogen atom, a linear alkyl group, or an aryl group which may have a substituent,
R⁵ represents a hydrogen atom, an alkyl group, or an aryl group which may have a substituent, and
n represents an integer of 2 to 20, 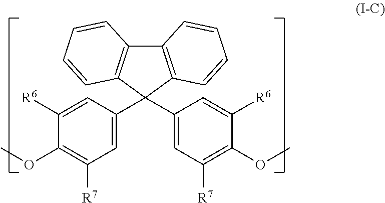
in Formula (I-C), R⁶ and R⁷ represent a hydrogen atom, an alkyl group, or an aryl group which may have a substituent, 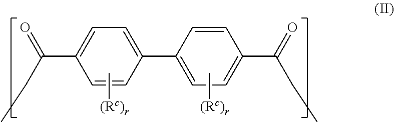
in Formula (II), R^{c} represents an alkyl group, an aryl group which may have a substituent, or a halogen atom, and
r represents an integer of 0 to 4.

2. The laminate according to claim 1,
wherein the polymer layer further contains a liquid crystal polymer different from the polyarylate.

3. The laminate according to claim 1,
wherein the polyarylate has a crosslinking structure.

4. The laminate according to claim 1,
wherein the polyarylate has only a repeating unit represented by Formula (I-Aa) as the repeating unit I,

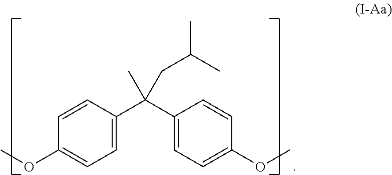

5. The laminate according to claim 2,
wherein the polyarylate has a crosslinking structure.

6. The laminate according to claim 2,
wherein the polyarylate has only a repeating unit represented by Formula (I-Aa) as the repeating unit I,

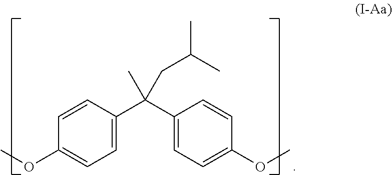

7. The laminate according to claim 3,
wherein the polyarylate has only a repeating unit represented by Formula (I-Aa) as the repeating unit I, [chemical structure]
